(19) United States
(12) Patent Application Publication
(10) Pub. No.: US 2024/0147655 A1
(43) Pub. Date: May 2, 2024

(54) FAN-COOLED BATTERY CHARGER FOR ELECTRONIC DEVICES

(71) Applicant: Emmanuel Garcia Rodriguez, La Union, Murcia (ES)

(72) Inventor: Emmanuel Garcia Rodriguez, La Union, Murcia (ES)

(21) Appl. No.: 18/126,392

(22) Filed: Mar. 25, 2023

(30) Foreign Application Priority Data
Oct. 26, 2022 (ES) U202231772

(51) Int. Cl. H05K 7/20; H02J 7/00

(52) U.S. Cl. CPC H05K 7/20145; H02J 7/00309; H05K 7/20172

(57) ABSTRACT

The invention, refers to a fan-cooled battery charger for electronic devices, contributing, to its intended function, advantages and characteristics, described in detail below, which represent an improvement on the current state of the art. The proposed fan-cooled battery charger for electronic devices constitutes a suitable solution to the described problem which, in turn, represents an improvement over what is currently known, the distinctive details which make it possible and make it distinguishable.

### OBJECT OF THE INVENTION

The invention, as expressed in the statement of this specification, refers to a fan-cooled battery charger for electronic devices, contributing, to its intended function, advantages and characteristics, described in detail below, which represent an improvement on the current state of the art.

More specifically, the object of the invention focuses on a battery charger, of the type constituting an accessory connectable to a mains power supply socket for recharging the battery of different types of electronic devices, in particular cell phones, but also electronic tablets, laptops or others, to which it is connected through a cable with USB connector, which, being of a type consisting of two or more separate USB connection ports to convert it into a charger for universal use and to be able to use it in the battery recharging of different types of devices, is essentially distinguished by its cooling system which, driven by an internal fan, provides a flow of cold air inlet and hot air outlet, bringing, among others, the advantage of extending the life of the battery of the device it recharges.

### FIELD OF APPLICATION OF THE INVENTION

The field of application of this invention is framed within the sector of the industry dedicated to the manufacture of battery recharging accessories for electronic devices, focusing particularly on the field of wall socket connection chargers.

### BACKGROUND OF THE INVENTION

Multiple types and models of chargers for cell phones and other electronic devices, such as tablets, computers, speakers, etc., are known as the state of the art.

One of the problems with this type of accessory is that many devices have different USB connectors so each device requires a charger with a specific USB connection port.

To solve this problem, some chargers already have two or more different connection ports.

However, another problem with this type of accessory is the heating of the charger during the charging process which, if it is not fast charging or “Quick Charge Technology”, can take a long time and, as a consequence, cause deterioration both in the electronic components and motherboard of the charger itself and in the battery of the device, since, in turn, this increase in temperature slows down the charging time.

Charger temperature has been proven to directly affect the battery life of cell phones or other electronic devices.

The goal of this invention is, therefore, to provide the market with a new type of charger improved to avoid the said problem.

On the other hand, and as a reference to the present state of the art, it should be noted that, although other battery chargers of the type here referred to are known, at least as far as the applicant is concerned, it is not known of the existence of any other charger with technical and structural characteristics equal or similar to those of the one claimed herein.

### Explanation of the Invention

The proposed fan-cooled battery charger for electronic devices constitutes a suitable solution to the described problem which, in turn, represents an improvement over what is currently known, the distinctive details which make it possible and make it distinguishable are conveniently included in the final claims attached to the present description.

What the invention proposes, as noted above, is a battery charger accessory, of the type connectable to a mains power supply socket for recharging the battery of one or more electronic devices, in particular cell phones, but also electronic tablets, laptops or others, to which it is connected via a cable with USB connector in at least one connection port of compatible type, which is distinguished, essentially, by the fact of comprising a cooling system that, thanks to some means of air impulsion, preferably an internal fan, provides a flow of cold air inlet and hot air outlet, providing, among others, the advantage of avoiding the charger temperature increase, which, in turn, allows to increase the charging speed and, at the same time, to extend the life of the battery of the device that is recharging.

For this purpose, preferably, the body of the charger has holes intended for the passage of suction or expulsion of air that allows the forced airflow that drives the fan to cool the charger inside.

Preferably, the fan is of the quiet type. 15.9 decibels. With a rotational speed of 5000 rpm. which generates a maximum flow rate of 50.7 l/m.

Since the charger will have a forced airflow inside, dust and dirt may get inside, which could cause malfunction. To avoid this passage of dust into the interior of the charger body, the holes provided in the charger walls for the passage of air are preferably covered internally with filters made of a Nylon fabric or similar with a mesh opening of 0.2 mm.

In a preferred embodiment, the charger of the invention consists, essentially, of a hollow and closed body so that the user cannot disassemble or manipulate its interior. This body is formed, in turn, by two elements: a housing and a modular connector assembly with the plug connected to the wall outlet, which is coupled as a closure of the front face of the housing.

The housing is designed in such a way that it defines a case in which the various internal components of the charger, i.e. the base plate, fan, fan holder and filters of the air passage holes, are fitted or interlocked inside the housing.

And, for its part, the modular connector assembly with the plug is designed to allow the manufacturer, simply, to be able to assemble it with different types of plugs, for example, flat or round, depending on the type of plug used in the market to which the charger is intended to be marketed. In this way, the same housing can be used for different types of plugs.

Preferably, the charger has up to four different USB connection ports to make it a universal charger for use in recharging the batteries of different types of devices.

Consequently, the charger object of the invention is configured as a practical wall-mounted mobile charger accessory with a cold air inlet and hot air outlet, driven by a fan, which ensures that the charger never rises in temperature, increasing the charging speed and, in turn, increasing the service life of the battery of the mobile or electronic device.

Also, the charger, having a small size, is an accessory of universal compatibility, allowing charging the battery of both tablets and laptops or others.

Lastly, it should be noted that, preferably, the charger incorporates Quick Charge Technology, which supplies current faster than conventional charging, recovering thirty percent of the battery charge in just over five minutes.

### DRAWINGS DESCRIPTION

To complement the description and to assist in a better understanding of the features of the invention, this specification is accompanied, as an integral part thereof, by a set of drawings in which the following has been portrayed in an explanatory and non-limiting manner:

FIGS. 1 and 2—Show two upper perspective views, taken from a rear and front point of view respectively, of an exemplary embodiment of the fan-cooled battery charger for electronic devices, the object of the invention, showing its general external configuration.

FIG. 3—Shows a front elevation view of the example of the charger, according to the invention shown in FIGS. 1 and 2.

FIG. 4—Shows a rear elevation view of the example of the charger of the invention shown in FIGS. 1 to 3.

FIG. 5—Shows a lower plan view of the charger of the invention shown in FIGS. 1 to 4.

FIG. 6—Shows a side elevation view of the exemplary embodiment of the invention shown in FIGS. 1 to 5.

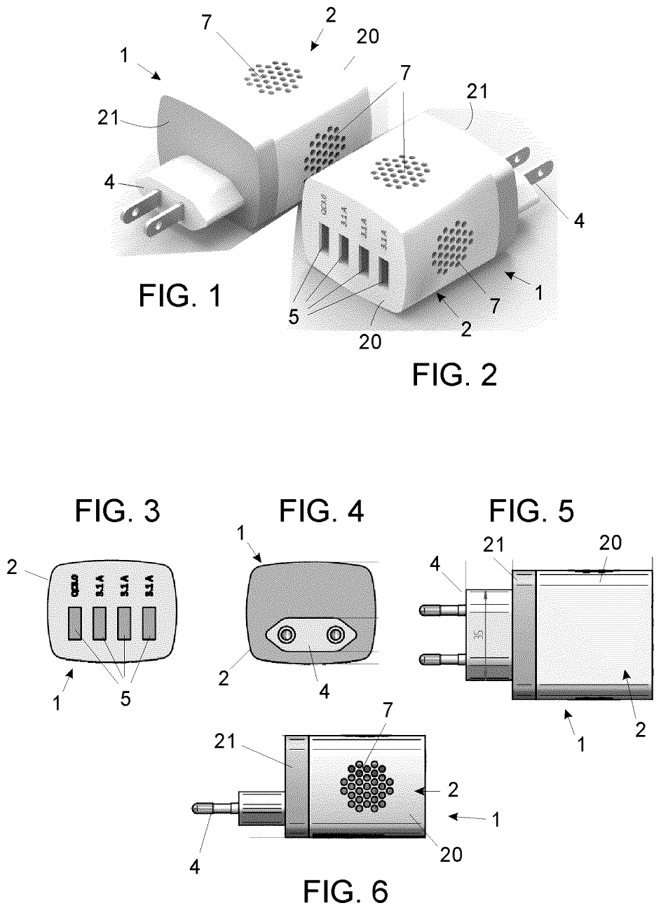

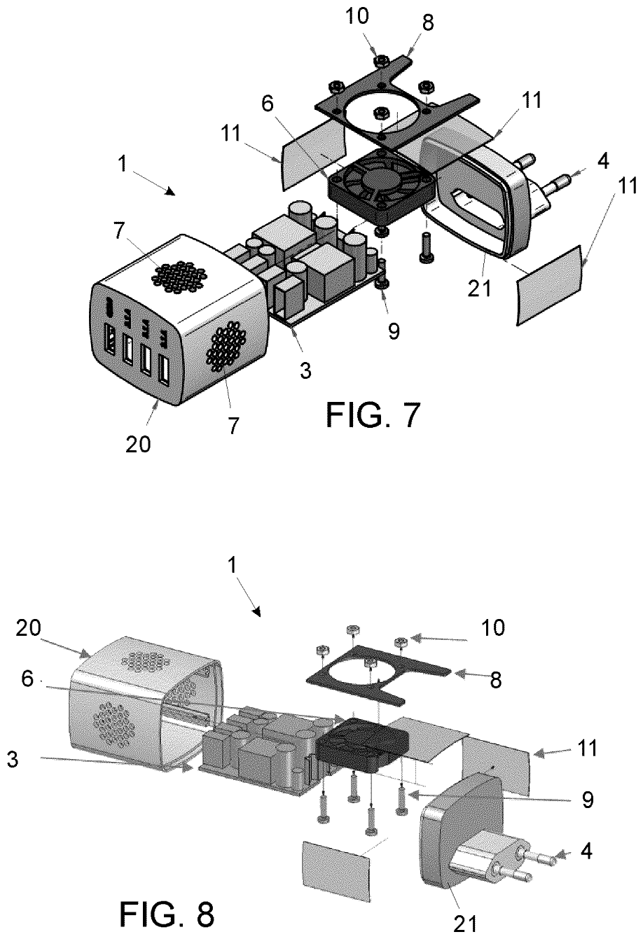

FIG. number 7—Shows a side-front perspective view of the exemplary charger, according to the invention, shown in the preceding figures, in this case, represented in an exploded view, showing the main parts and elements both externally and internally.

And FIG. 8—Shows a side-rear perspective and exploded view of the exemplary charger shown in FIG. 7.

### PREFERRED EMBODIMENT OF THE INVENTION

Given the aforementioned figures, and following the adopted numbering, a non-limiting exemplary embodiment of the fan-cooled battery charger for electronic devices can be observed therein, which includes what is indicated and described in detail below.

Thus, as can be seen in the figures, the invention charger (1) is one of those known to include a hollow body (2) that internally houses a base plate (3) that connects with a plug (4) that emerges to the outside on one of its sides and, at least, with a USB connection port (5) located on the opposite side.

And, from this already known configuration, the charger (1) is essentially distinguished by the fact of including, also housed in its body (2), a cooling means (6) which, by connecting the plug (4) and having an electric current, determines the air impulsion from the inside of the body (2) creating a flow of cold air inlet and hot air outlet.

Preferably, the cooling means includes at least one electric fan (6) connected to the base plate (3).

Preferably, the body (2) of the charger (1) presents one or more holes (7) or groups of holes (7) in at least two opposite walls thereof, intended to allow the passage of the intake and exhaust airflow driven by the fan (6) to cool the interior of the charger. Preferably, the body (2) has respective groups of holes (7) in three of its walls.

Preferably, the fan (6) is attached to a support (8) provided for this purpose inside the body (2) of the charger (1).

Preferably, the fan (6) is fixed to the support (8) using screws (9) and nuts (10).

Preferably, the support (8) is fixed to the inside of the body (2) using a press-fit coupling.

Preferably, the fan (6) is of the silent type, 15.9 decibels and with a rotation speed of 5000 rpm. which generates a maximum flow rate of 50.7 l/m.

Preferably, the holes (7) of the body (2) of the charger (1) are internally covered with filters (11) to prevent the entry of dust. Preferably, filters (11) are made of a Nylon fabric or similar with a mesh opening of 0.2 mm.

In a preferred embodiment, the body (2) of the charger (1) comprises up to four different USB connection ports (5).

In a preferred embodiment, the body (2) of the charger (1) has two parts:
a housing (20), with a sort of parallelepiped configuration, sized to accommodate inside it all the functional elements of the charger (1), i.e. base plate (3), the USB connection ports (5), the fan (6) with its support (8) and the filters (11), and one of its sides open, and
an interchangeable modular connector assembly (21) consisting of a closing wall, which fits tightly into the open side of the housing (20), and the plug (4), allowing the manufacturer to assemble the charger (1) with different types of plug (4) by changing only the modular connector assembly (21).

Having sufficiently described the nature of the present invention, as well as the manner of implementing it, it is not considered necessary to further explain it so that any person skilled in the art may understand its scope and the advantages derived therefrom, it is noted that, within its importance, it may be implemented in other forms of embodiment which differ in detail from the one indicated by way of example, and to which the protection claimed will also apply provided that its fundamental principle is not altered, changed or modified.

1. FAN-COOLED BATTERY CHARGER FOR ELECTRONIC DEVICES, comprising a hollow body (2) internally housing a base plate (3) connecting to a plug (4) which emerges to the outside on one of its sides and, at least, to a USB connection port (5) located on the opposite side, is distinguished by including, also housed in its body (2), a cooling means (6) which, when the plug (4) is connected and has electric current, determines the impulsion of the air inside the body (2) creating a flow of cold air inlet and hot air outlet.

2. FAN-COOLED BATTERY CHARGER FOR ELECTRONIC DEVICES according to claim 1, is characterized in that the cooling means comprises, at least, an electric fan (6) connected to the base plate (3).

3. FAN-COOLED BATTERY CHARGER FOR ELECTRONIC DEVICES according to claim 2, is characterized in that the body (2) of the charger (1) has one or more holes (7) in at least two opposite walls thereof, intended to allow the passage of the suction and expulsion airflow that drives the fan (6) to cool the inside of the charger.

4. FAN-COOLED BATTERY CHARGER FOR ELECTRONIC DEVICES according to claim 3, is characterized in that the fan (6) is attached to a support (8) provided for this purpose inside the body (2) of the charger (1).

5. FAN-COOLED BATTERY CHARGER FOR ELECTRONIC DEVICES according to claim 4, is characterized in that the fan (6) is fixed to the support (8) using screws (9) and nuts (10).

6. FAN-COOLED BATTERY CHARGER FOR ELECTRONIC DEVICES according to claim 5, is characterized in that the support (8) is fixed to the inside of the body (2) using a press-fit coupling.

7. FAN-COOLED BATTERY CHARGER FOR ELECTRONIC DEVICES according to any of the claims 2 to 6, is characterized in that the fan (6) is of the silent type, 15.9 decibels, with a rotation speed of 5000 rpm. which generates a maximum flow rate of 50.7 l/m.

8. FAN-COOLED BATTERY CHARGER FOR ELECTRONIC DEVICES according to claim 3, is characterized in that the holes (7) of the body (2) of the charger (1) are internally covered with filters (11).

9. FAN-COOLED BATTERY CHARGER FOR ELECTRONIC DEVICES according to claim 8, is characterized in that filters (11) are made of Nylon fabric or similar and have a 0.2 mm mesh opening.

10. FAN-COOLED BATTERY CHARGER FOR ELECTRONIC DEVICES according to any of the previous claims, is characterized in that the body (2) comprises up to four different USB connection ports (5).

11. FAN-COOLED BATTERY CHARGER FOR ELECTRONIC DEVICES according to any of the preceding claims, is characterized in that the body (2) comprises:
a housing (20), sized to accommodate inside it the set of functional elements of the charger (1) and having one of its sides open, and
an interchangeable modular connector assembly (21) consisting of a closing wall, which fits tightly into the open side of the housing (20), and the plug (4).
